(19) United States
(12) Patent Application Publication
(10) Pub. No.: US 2023/0395694 A1
(43) Pub. Date: Dec. 7, 2023

(54) GALLIUM NITRIDE HIGH ELECTRON MOBILITY TRANSISTOR

(71) Applicant: Taiwan Semiconductor Manufacturing Co., Lid., Hsinchu (TW)

(72) Inventors: Chan-Hong CHERN, Taipei City (TW); Yi-An LAI, Taipei City (TW)

(73) Assignee: Taiwan Semiconductor Manufacturing Co., Lid., Hsinchu (TW)

(21) Appl. No.: 18/188,984

(22) Filed: Mar. 23, 2023

Related U.S. Application Data
(60) Provisional application No. 63/383,843, filed on Nov. 15, 2022.
(60) Provisional application No. 63/349,550, filed on Jun. 6, 2022.

(51) Int. Cl. H01L 29/66; H01L 29/20; H01L 29/205; H01L 21/02; H01L 29/423

(52) U.S. Cl. CPC H01L 29/66462; H01L 29/2003; H01L 29/205; H01L 21/0254; H01L 21/0262; H01L 29/4236

(57) ABSTRACT

An efficient AlGaN/GaN High Electron Mobility Transistor (HEMT) device suitable for use in high frequency and high power applications is disclosed. By including a second AlGaN layer that is selectively deposited outside the gate region, it is possible to reduce on-resistance of the device without affecting the threshold voltage. Independent control of R_{ds}-on and threshold voltage Vₜₕ can therefore be achieved, resulting in enhanced performance.

### CROSS-REFERENCE TO RELATED APPLICATION

This patent application claims the benefit of U.S. Provisional Patent Application No. 63/383,843, filed on Nov. 15, 2022 and titled “Gallium Nitride High Electron Mobility Transistor,” and U.S. Provisional Patent Application No. 63/349,550, filed on Jun. 6, 2022 and titled “GaN Device with Low On-Resistance,” which are incorporated by reference herein in their entireties.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (FinFETs), and high electron mobility transistors (HEMTs). Such scaling down has increased the complexity of semiconductor manufacturing processes.

### BRIEF DESCRIPTION OF THE DRAWINGS

Aspects of the present disclosure are best understood from the following detailed description when read with the accompanying figures. It is noted that, in accordance with common practice in the industry, various features are not drawn to scale. In fact, the dimensions of the various features may be arbitrarily increased or reduced for clarity of discussion.

FIG. 1A is a cross-sectional view of a gallium nitride (GaN) HEMT device, in accordance with some embodiments of the present disclosure.

FIG. 1B is a schematic diagram showing the GaN HEMT device in the context of a circuit, in accordance with some embodiments of the present disclosure.

FIG. 2 is a flow diagram of a method for fabricating the GaN HEMT device shown in FIG. 1, in accordance with some embodiments of the present disclosure.

FIGS. 3-9 are cross-sectional views of the GaN HEMT device shown in FIG. 1, at various stages of its fabrication process, in accordance with some embodiments of the present disclosure.

### DETAILED DESCRIPTION

The following disclosure provides different embodiments, or examples, for implementing different features of the provided subject matter. Specific examples of components and arrangements are described below to simplify the present disclosure. These are, of course, merely examples and are not intended to be limiting. For example, the formation of a first feature on a second feature in the description that follows may include embodiments in which the first and second features are formed in direct contact, and may also include embodiments in which additional features may be formed that are between the first and second features, such that the first and second features are not in direct contact.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments of the present disclosure, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

High electron mobility transistors (HEMTs) are used in high frequency/high power applications (e.g., applications with applied voltages of 100 V or more), while metal oxide semiconductor field effect transistors (MOSFETs) operate at lower voltages (e.g., 5 V or 12 V) for use in devices such as microprocessors and memory. For example, gallium nitride (GaN) HEMT devices can achieve higher performance, a wider operational bandwidth in a smaller form factor, and greater power aided efficiency (PAE) compared to silicon-based HEMTs. Consequently, it is advantageous to use GaN HEMTs for power applications, such as power converters for down-converting high voltages (e.g., 220 V to 110 V), dual voltage power supplies, high voltage electric vehicle batteries, and AC-to-DC converters. GaN HEMTs can also be used for radio frequency (RF) communication devices, such as power amplifiers (PAs), switches, and low noise amplifiers (LNAs) in satellite communication systems and cellular networks.

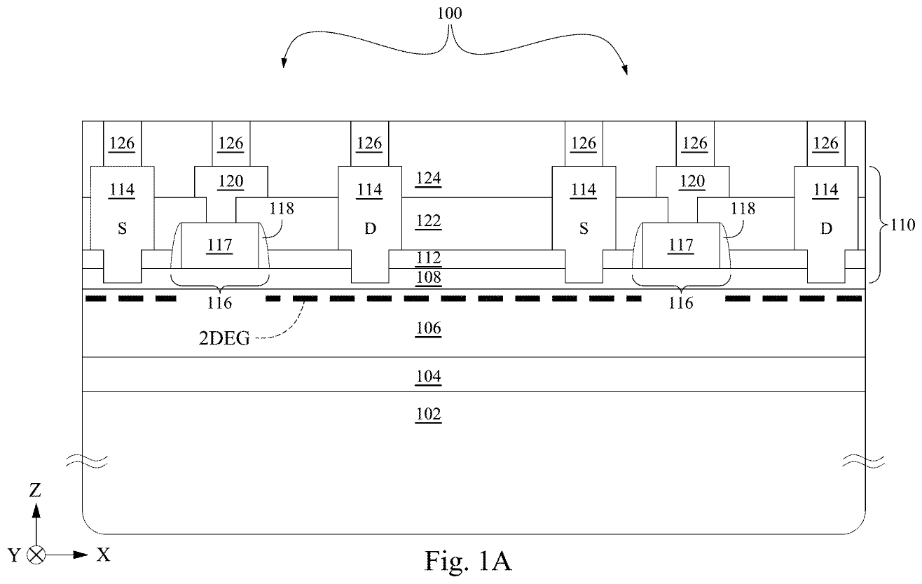

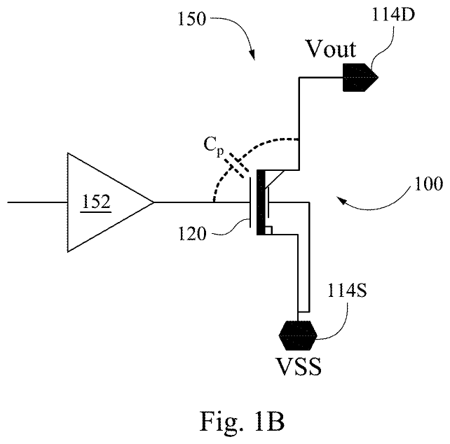

FIG. 1A shows a cross-section of side-by-side GaN HEMT devices 100 that feature a low on-resistance, according to some embodiments of the present disclosure. GaN HEMT devices 100 are fabricated on a substrate 102. In some embodiments of the present disclosure, a transition/buffer layer 104 is formed on substrate 102. A channel layer 106 is formed on transition/buffer layer 104. A HEMT device layer 110 is formed on channel layer 106.

In some embodiments of the present disclosure, HEMT device layer 110 includes a first aluminum gallium nitride (AlGaN) layer, AlₓGa₁₋ₓN layer 108, and a second AlGaN layer, on-resistance reduction layer 112 formed on AlₓGa₁₋ₓN layer 108. HEMT device layer 110 containing these AlGaN layers is formed on channel layer 106, causing a two dimensional electron gas to form in a conduction channel below a top surface of channel layer 106. The two dimensional electron gas is a polarization induced sheet charge formed at the interface of AlGaN and GaN layers. Both piezoelectric polarization and spontaneous polarization effects can contribute to the formation of the two dimensional electron gas.

HEMT device layer 110 further includes a source/drain ohmic layer 114 that connects to AlₓGa₁₋ₓN layer 108. HEMT device layer 110 further includes a first gate structure 116 formed over AlₓGa₁₋ₓN layer 108. In some embodiments of the present disclosure, first gate structure 116 includes a p-type GaN structure 117 and sidewall spacers 118. In some embodiments of the present disclosure, HEMT device layer 110 further includes a second gate structure 120 coupled to first gate structure 116, and a passivation layer 122 between source, drain, and gate terminals of the HEMT devices.

In some embodiments of the present disclosure, an ILD layer 124 is formed above HEMT device layer 110. Contacts 126 pass through ILD layer 124 to couple to source/drain ohmic layer 114 and second gate structures 120.

FIG. 1B shows a single GaN HEMT device 100 in the context of a circuit 150, according to some embodiments of the present disclosure. Circuit 150 includes GaN HEMT device 100 electrically connected to a driver stage 152 configured to apply a voltage to a gate terminal of GaN HEMT device 100 (e.g., second gate structure 120). In response to the applied voltage reaching a threshold voltage Vₜₕ, a source voltage Vss (e.g., ground) at source terminal 114S will appear at drain terminal 114D as an output voltage Vₒᵤₜ, to which a load can be connected.

During a transition from low voltage to high voltage, if signal noise causes a voltage spike (dI/dt) to occur, a parasitic Miller capacitance Cₚ can develop between the gate and drain terminals of GaN HEMT device 100. However, when threshold voltage Vₜₕ is sufficiently high, this inductive effect is mitigated. It is desirable for the threshold voltage of GaN HEMT device 100 to be in the range of about 2.0 V to about 2.5 V to withstand such a voltage spike and to prevent the voltage spike from inadvertently turning on GaN HEMT device 100, according to some embodiments of the present disclosure.

Also, it is desirable for the on-resistance R_{ds}-on of GaN HEMT device 100 to be as small as possible to reduce power dissipation. Thus, according to some embodiments of the present disclosure, the design criteria for GaN HEMT device 100 can include reducing R_{ds}-on without affecting the threshold voltage Vₜₕ. In some embodiments of the present disclosure, to reduce R_{ds}-on, the thickness of AlₓGa₁₋ₓN layer 108 can be increased. In some embodiments of the present disclosure, R_{ds}-on can be reduced by increasing the aluminum concentration in AlₓGa₁₋ₓN layer 108. Both of these modifications will increase the two dimensional electron gas concentration, thereby enhancing spontaneous polarization and piezo-electric polarization of GaN HEMT device 100. However, increasing the thickness of or the aluminum concentration in AlₓGa₁₋ₓN layer 108 may also reduce the threshold voltage Vₜₕ of GaN HEMT device 100.

In some embodiments of the present disclosure, on-resistance R_{ds}-on can be de-coupled from threshold voltage Vₜₕ by forming on-resistance reduction layer 112 on AlₓGa₁₋ₓN layer 108. Because on-resistance reduction layer 112 is present on either side of a p-type GAN (pGaN) structure 117 but not directly underneath pGaN structure 117, threshold voltage Vₜₕ is unaffected by the addition of on-resistance reduction layer 112, while on-resistance R_{ds}-on is reduced. In some embodiments, the on-resistance R_{ds}-on can be reduced to between about 0.1 mohm/mm and about 0.25 mohm/mm. Independent control of R_{ds}-on and threshold voltage Vₜₕ can therefore be achieved by inserting on-resistance reduction layer 112.

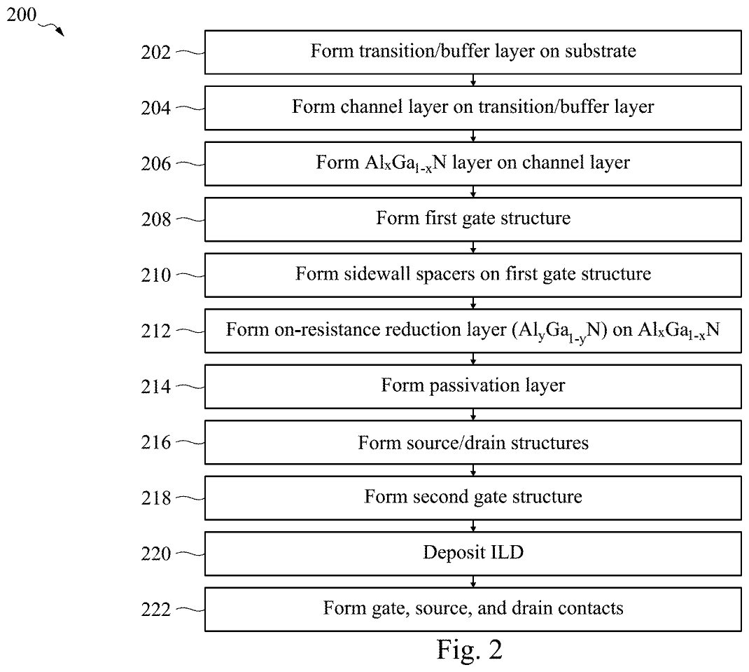

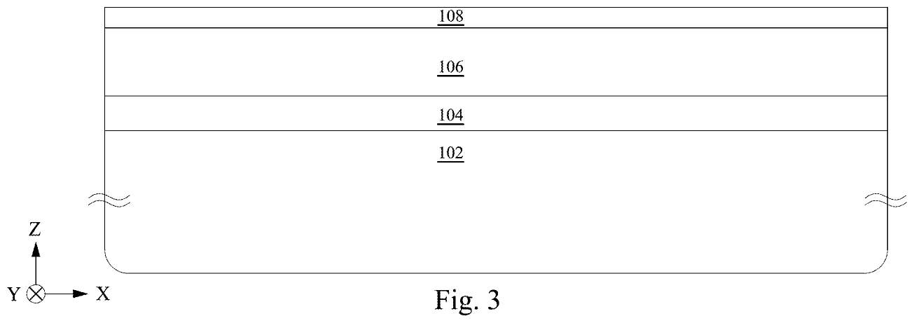

FIG. 2 illustrates a method 200 for fabricating a GaN HEMT device 100 having a low on-resistance, according to some embodiments of the present disclosure. For illustrative purposes, operations illustrated in FIG. 2 will be described with reference to processes for fabricating semiconductor structures as illustrated in FIGS. 3-9, which are cross-sectional views of GaN HEMT device 100 at various stages of its fabrication, according to some embodiments of the present disclosure. Operations of method 200 can be performed in a different order, or not performed, depending on specific applications. It is noted that method 200 may not produce a complete GaN HEMT device. Accordingly, it is understood that additional processes can be provided before, during, or after method 200, and that some of these additional processes may be briefly described herein.

Referring to FIG. 2, in operations 202, 204, and 206, transition/buffer layer 104, channel layer 106, and AlₓGa₁₋ₓN layer 108, respectively, are formed as blanket layers on substrate 102 as shown in FIG. 3, according to some embodiments of the present disclosure.

In operation 202, transition/buffer layer 104 is formed on substrate 102. As used herein, the term “substrate” describes a material onto which subsequent material layers are added. Substrate 102 may be patterned. Materials added on substrate 102 may be patterned or may remain unpatterned. Substrate 102 can be a bulk semiconductor wafer or the top semiconductor layer of a semiconductor-on-insulator (SOI) wafer (not shown), such as silicon-on-insulator. In some embodiments of the present disclosure, substrate 102 can include a crystalline semiconductor layer with its top surface parallel to the (111) crystal plane. Substrate 102 can be made of a semiconductor material such as, but is not limited to, silicon (Si). In some embodiments of the present disclosure, substrate 102 can include (i) an elementary semiconductor, such as germanium (Ge); (ii) a compound semiconductor including silicon carbide (SiC), gallium arsenide (GaAs), gallium phosphide (GaP), indium phosphide (InP), indium arsenide (InAs), and/or indium antimonide (InSb); (iii) an alloy semiconductor including silicon germanium carbide (SiGeC), silicon germanium (SiGe), gallium arsenic phosphide (GaAsP), gallium indium phosphide (InGaP), gallium indium arsenide (InGaAs), gallium indium arsenic phosphide (InGaAsP), aluminum indium arsenide (InAlAs), and/or aluminum gallium arsenide (AlGaAs); or (iv) a combination thereof. Alternatively, substrate 102 can be made from an electrically non-conductive material, such as a glass or a sapphire wafer, or a plastic material.

In some embodiments of the present disclosure, transition/buffer layer 104 is an epitaxially grown layer of aluminum nitride (AlN). In some embodiments of the present disclosure, transition/buffer layer 104 is a composition of epitaxially grown layers of aluminum nitride (AlN) layer, AlGaN grading layer, AlN/GaN and or AlGaN/GaN superlattice layer with a total thickness between 3 um and 6 um. In some embodiments of the present disclosure, transition/buffer layer 104 can be an epitaxially grown GaN/AlGaN superlattice made up of alternating layers of GaN and AlGaN grown on top of one another. Any number of alternating layers of GaN and AlGaN can be included in transition/buffer layer 104. In some embodiments of the present disclosure, transition/buffer layer 104 can have a same crystallographic orientation as a top surface of substrate 102.

In operation 204, channel layer 106 is formed on transition/buffer layer 104. In some embodiments of the present disclosure, channel layer 106 is a layer of GaN that is grown epitaxially on transition/buffer layer 104 to a thickness of about 1000 Å. In some embodiments of the present disclosure, channel layer 106 can be up to 1.5 microns thick.

In operation 206, AlₓGa₁₋ₓN layer 108 is formed on channel layer 106. In some embodiments of the present disclosure, AlₓGa₁₋ₓN layer 108 is grown epitaxially on channel layer 106. Alternatively, layer 108 can be made of AlₓIn₁₋ₓN. In some embodiments of the present disclosure, AlₓGa₁₋ₓN layer 108 can have a thickness between about 150 Å and about 300 Å, for example, about 200 Å. In some embodiments of the present disclosure, the value of x can be in the range of about 0.15 to about 0.2, or about 15% to about 20%. The interface between AlₓGa₁₋ₓN layer 108 and the GaN material of channel layer 106, or the AlₓGa₁₋ₓN/GaN heterojunction, induces a two dimensional electron gas to form in an upper region of channel layer 106.

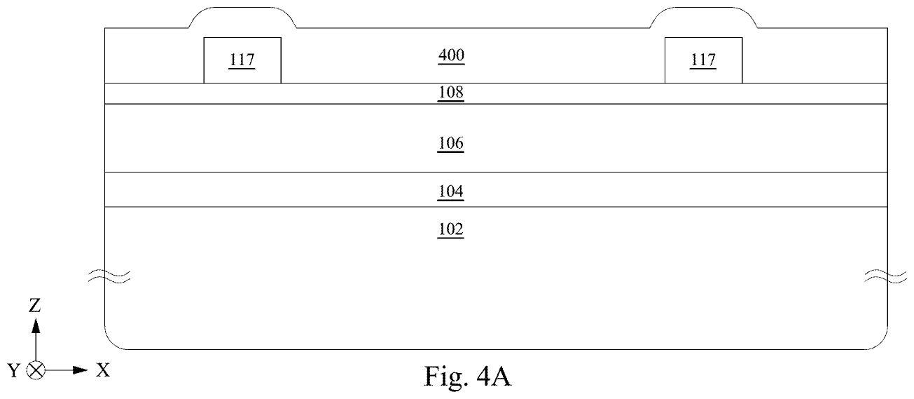

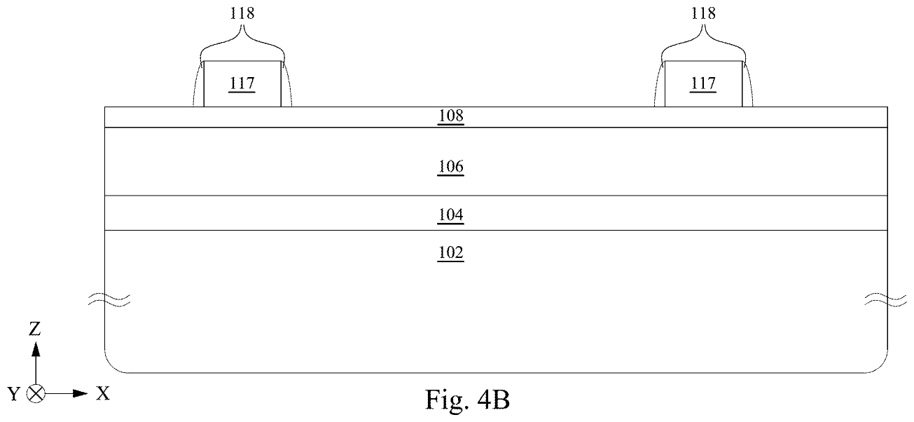

Referring to FIG. 2, in operation 208, first gate structures 116 are formed on AlₓGa₁₋ₓN layer 108 as shown in FIG. 4A, according to some embodiments of the present disclosure. In some embodiments of the present disclosure, each of first gate structures 116 is a p-type GaN, or pGaN structure 117. A pGaN layer can be deposited by chemical vapor deposition (CVD), low pressure chemical vapor deposition (LPCVD), plasma enhanced chemical vapor deposition (PECVD), high density plasma CVD (HDPCVD), atomic layer deposition (ALD), ultrahigh vacuum CVD (UHVCVD), reduced pressure CVD (RPCVD), or any other suitable deposition process. In some embodiments of the present disclosure, the pGaN layer can have a thickness of at least about 300 Å. The pGaN layer can then be patterned using a photoresist mask to define pGaN structures 117, as shown in FIG. 4A. In some embodiments of the present disclosure, pGaN structures 117 can be made of gallium nitride that is doped with a positive species, such as magnesium. In some embodiments of the present disclosure, the doping concentration of pGaN structures 117 can be about 1×10¹⁸ cm⁻³ to about 1×10¹⁹ cm⁻³.

When a voltage is applied to pGaN structures 117, the polarization effect causes a two dimensional electron gas to form in channel layer 106, directly underneath pGaN structures 117, thus causing the two dimensional electron gas to become continuous along the upper region of channel layer 106. When a voltage exceeding the threshold voltage is applied, the two dimensional electron gas under the gate is enhanced sufficiently to conduct a current within channel layer 106.

In some embodiments, the presence of AlₓGa₁₋ₓN layer 108 directly underneath pGaN structures 117 permits AlₓGa₁₋ₓN layer 108 to control, either partially or fully, the threshold voltage Vₜₕ of GaN HEMT device 100. The threshold voltage Vₜₕ, in turn, determines whether or not GaN HEMT device 100 switches on in response to a voltage applied to pGaN structures 117.

Referring to FIG. 2, in operation 210, sidewall spacers 118 are formed on pGaN structures 117 as shown in FIGS. 4A and 4B, according to some embodiments of the present disclosure. First, a spacer layer 400 can be deposited conformally over AlₓGa₁₋ₓN layer 108 and pGaN patterned structures 117, as shown in FIG. 4A, using CVD, LPCVD, PECVD, UHVCVD, RPCVD, HDPCVD, ALD, or any other suitable deposition process, at a thickness comparable to that of pGaN patterned structures 117. In some embodiments of the present disclosure, spacer layer 400 can be made of a semiconductor (e.g., Si, Ga), an oxide, a nitride, an oxynitride, or a combination thereof. Spacer layer 400 can then be etched anisotropically in a downward (−z) direction using a reactive ion etching (RIE) process, thus leaving behind sidewall spacers 118 as shown in FIG. 4B, where the width of sidewall spacers 118 depends on the thickness of pGaN structures 117.

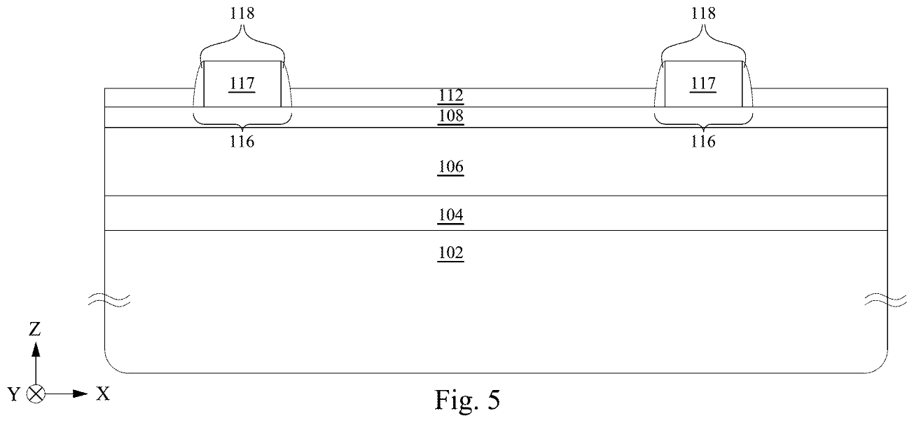

Referring to FIG. 2, in operation 212, on-resistance reduction layer 112 can be formed on AlₓGa₁₋ₓN layer 108 as shown in FIG. 5, according to some embodiments of the present disclosure. In some embodiments of the present disclosure, on-resistance reduction layer 112 can be an Al_{y}Ga_{1-y}N layer that is deposited by selective epitaxial growth (SEG) onto exposed regions of AlₓGa₁₋ₓN layer 108 adjacent to sidewall spacers 118. The notation Al_{y}Ga_{1-y}N indicates that the compositions of the first and second AlGaN layers are different from one another. In particular, the aluminum concentration and the gallium concentration of on-resistance reduction layer 112 are different from corresponding concentrations in AlₓGa₁₋ₓN layer 108. In some embodiments of the present disclosure, y is greater than x, such that the aluminum concentration of on-resistance reduction layer 112 is greater than the aluminum concentration of AlₓGa₁₋ₓN layer 108. In some embodiments of the present disclosure, the value of y can be in the range of about 0.4 to about 0.5, or about 40% to about 50%.

On-resistance reduction layer 112 tends increases the spontaneous polarization and piezoelectric polarization that occurs below AlₓGa₁₋ₓN layer 108, thus decreasing the on-resistance of GaN HEMT device 100 accordingly. The polarization induced two dimensional electron gas is also sensitive to the thickness of on-resistance reduction layer 112, such that as the thickness of the Al_{y}Ga_{1-y}N layer increases, the polarization effect on channel layer 106 increases, and the on-resistance of the GaN HEMT device 100 decreases.

In some embodiments of the present disclosure, the mechanism by which the Al_{y}Ga_{1-y}N in on-resistance reduction layer 112 affects the two dimensional electron gas is by diffusion of aluminum into AlₓGa₁₋ₓN layer 108, thereby increasing the Al concentration, which, in turn, increases the polarization effect within channel layer 106. Once on-resistance reduction layer 112 is deposited, sidewall spacers 118 are disposed to block lateral diffusion of aluminum from the Al_{y}Ga_{1-y}N layer into the region of AlₓGa₁₋ₓN layer 108 that is underneath gate structures 116, while permitting downward diffusion of aluminum from the Al_{y}Ga_{1-y}N layer into the region of AlₓGa₁₋ₓN layer 108 that is not underneath gate structures 116. Consequently, the threshold voltage of gate structures 116 remains substantially unaffected by the presence of the additional Al_{y}Ga_{1-y}N layer, while R_{ds}-on is reduced via diffusion of the aluminum into the regions of AlₓGa₁₋ₓN layer 108 between gate structures 116. Thus, on-resistance R_{ds}-on and threshold voltage Vₜₕ are de-coupled, such that control of the threshold voltage is maintained by AlₓGa₁₋ₓN layer 108 (which extends under gate structures 116), while the Al_{y}Ga_{1-y}N layer (which does not extend under gate structures 116) controls the on-resistance R_{ds}-on of GaN HEMT device 100.

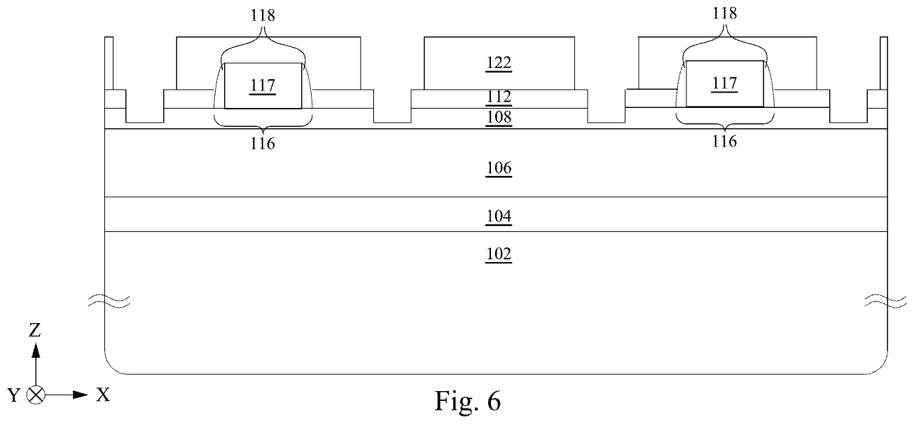

Referring to FIG. 2, in operation 214, passivation layer 122 can be formed as shown in FIG. 6, according to some embodiments of the present disclosure. In some embodiments of the present disclosure, passivation layer 122 can be deposited as a blanket layer covering on-resistance reduction layer 112 and gate structures 116. In some embodiments of the present disclosure, passivation layer 122 can be made of oxide, nitride, or oxynitride. In some embodiments of the present disclosure, passivation layer 122 has a thickness in the range of about 1000 Å to about 2000 Å. For forming passivation layer 122, a deposition process, such as CVD, PECVD, and spin coating, can be performed. A subsequent polishing process, such as a chemical mechanical polishing (CMP) process, can substantially planarize top surfaces of passivation layer 122.

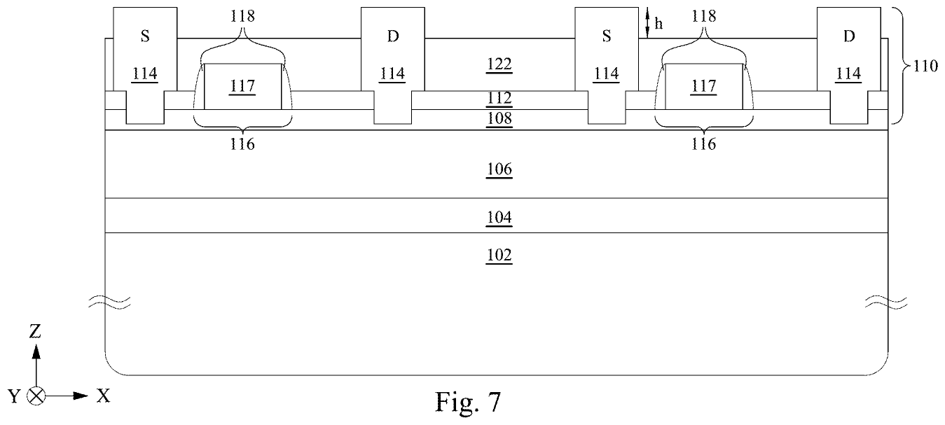

Referring to FIG. 2, in operation 216, source/drain ohmic layer 114 can be formed in passivation layer 122 as shown in FIGS. 6 and 7, according to some embodiments of the present disclosure. Referring to FIG. 6, trenches can be patterned using a photolithography process that employs a photoresist mask, a hard mask, or combinations thereof.

In a first etching operation, passivation layer 122 can be patterned using a dry etching process (e.g., reaction ion etching) or a wet etching process. In some embodiments of the present disclosure, gas etchants used in the dry etching process can include fluorine chemistries, such as sulfur hexafluoride (SF₆) or carbon tetrafluoride (CF₄). In some embodiments of the present disclosure, a hot phosphoric acid wet etch process can be used to pattern passivation layer 122, or a dry etch followed by a wet etch process can be used to pattern passivation layer 122.

In a second etching operation, etching can continue through on-resistance reduction layer 112, extending partially into AlₓGa₁₋ₓN layer 108. In some embodiments of the present disclosure, sidewall polymers that accumulate during the passivation etch may serve to reduce the critical dimension (CD) of the source/drain regions within the AlGaN layers compared with that of passivation layer 122. In some embodiments of the present disclosure, for the top of the T-shaped S/D regions is between 2 um and 3 um. In some embodiments of the present disclosure, for the bottom of the T-shaped S/D regions is between 1.5 um and 2.5 um. A plasma metal etching process can be used to continue etching anisotropically through on-resistance reduction layer 112 to stop within AlₓGa₁₋ₓN layer 108, before reaching the GaN boundary. The trench for source/drain ohmic layer 114 can be partially recessed into AlₓGa₁₋ₓN layer 108 so that when it is filled, source/drain ohmic layer 114 achieves ohmic contact with AlₓGa₁₋ₓN layer 108.

In some embodiments of the present disclosure, the etching operations can be followed by one or more wet cleaning steps to remove the sidewall polymer and other residues. Following the first and second etching operations, the cross-sectional view of the GaN HEMT device 100 is as shown in FIG. 6.

In some embodiments of the present disclosure, on-resistance reduction layer 112 and AlₓGa₁₋ₓN layer 108 can be patterned and etched to form AlGaN trenches prior to depositing passivation layer 122. Then, deposited passivation layer 122 can be patterned and etched to form passivation trenches that are wider than the AlGaN trenches. The passivation trenches together with the AlGaN trenches form T-shaped trenches as shown in FIG. 6.

Referring to FIG. 2, in operation 216, source/drain ohmic layer 114 can be formed in the T-shaped trenches, as shown in FIG. 7, according to some embodiments of the present disclosure. When the T-shaped trench formation is complete, both the passivation trenches and the AlGaN trenches can be filled to form source/drain ohmic layer 114 as shown in FIG. 7.

In some embodiments of the present disclosure, source/drain ohmic layer 114 is made of a metal or a metal alloy that can be formed in the T-shaped trenches by a plating process such as electroplating or electro-less plating. In some embodiments of the present disclosure, source/drain ohmic layer 114 can be made of a multilayer metal stack that can be formed in the T-shaped trenches by a multi-step deposition process. In some embodiments of the present disclosure, metals used in source/drain ohmic layer 114 can include, for example, titanium (Ti), Al, nickel (Ni), molybdenum (Mo), platinum (Pt), tantalum (Ta), iridium (Ir), or combinations thereof. The quality of source/drain ohmic layer 114 and the ohmic contact to on-resistance reduction layer 112 and AlₓGa₁₋ₓN layer 108 determines contact resistance (R_{c}), which can be a factor in the overall on-resistance R_{ds}-on of GaN HEMT device 100. In some embodiments of the present disclosure, formation of a high quality ohmic contact between source/drain ohmic layer 114 and the AlGaN/GaN heterojunction further includes an annealing operation, such as a high temperature rapid thermal anneal (RTA) process that can occur at about 800° C. to about 1000° C., or a low-temperature annealing process, such as a microwave anneal or a laser anneal.

In some embodiments of the present disclosure, following the formation of source/drain ohmic layer 114, passivation layer 122 can be recessed below top surfaces of source/drain ohmic layer 114 so that source/drain ohmic layer 114 extends above passivation layer 122 by a height h.

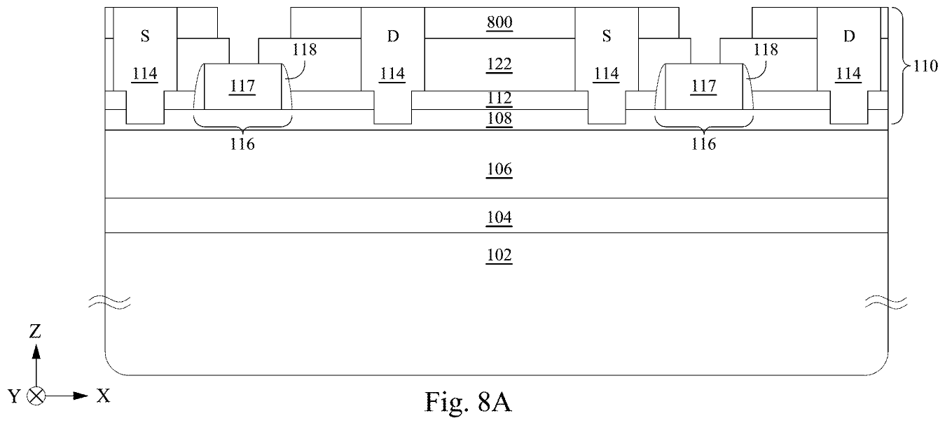

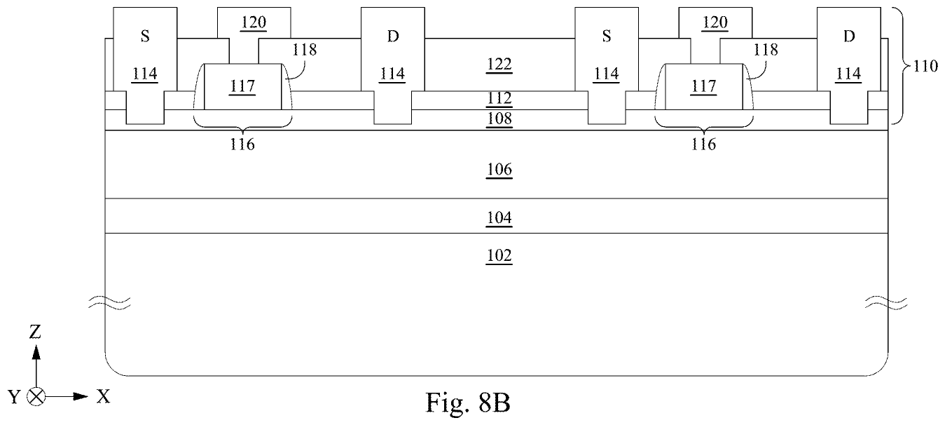

Referring to FIG. 2, in operation 218, second gate structures 120 can be formed over pGaN structures 117 as shown in FIGS. 8A and 8B, according to some embodiments of the present disclosure. In some embodiments of the present disclosure, gate trenches can be formed in passivation layer 122 over pGaN structures 117 using a first photoresist mask or hard mask (not shown). Then a second mask layer 800 can be formed on top of passivation layer 122. Second mask layer 800 can be a photoresist mask or a hard mask, for example, a silicon nitride (SiN) or silicon oxynitride (SiON) hard mask. In some embodiments of the present disclosure, second mask layer 800 has a thickness approximately equal to h so that second mask layer 800 is substantially co-planar with source/drain ohmic layer 114. Second mask layer 800 can then be patterned to form a T-shaped gate trench over pGaN structures 117, as shown in FIG. 8A. T-shaped gate trenches can then be filled to form metal gates as second gate structures 120. In some embodiments of the present disclosure, second gate structures 120 can be deposited as a multilayer metal stack. Such a multilayer metal stack can include, for example, a barrier metal layer, an interface layer, and a bulk metal. In some embodiments of the present disclosure, the barrier metal layer can be titanium nitride (TiN); the interface layer can be Ti, and the bulk metal can be aluminum-copper (Al Cu). Following deposition, the T-shaped metal gates can be polished using a ClVIP process, to be co-planar with source/drain ohmic layer 114 and second mask layer 800. Second mask layer 800 can then be removed to reveal the structure shown in FIG. 8B. Formation of second gate structures 120 completes HEMT device layer 110.

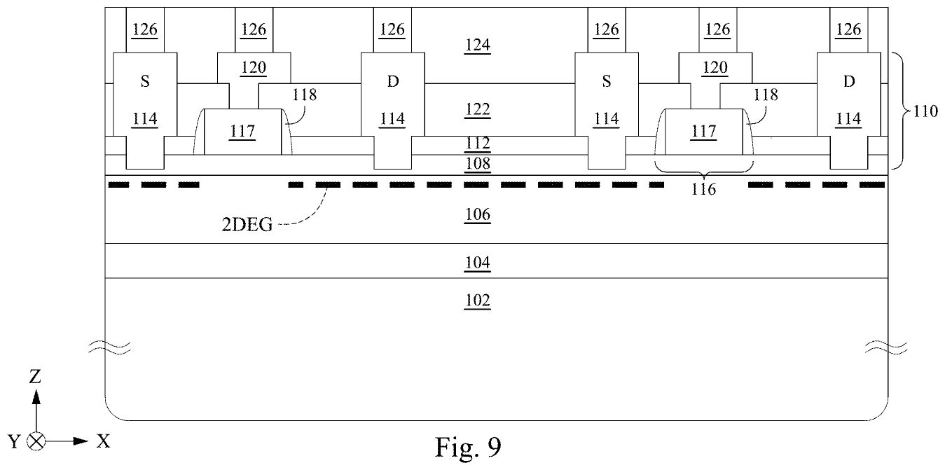

Referring to FIG. 2, in operation 220, ILD layer 124 can be formed to cover source/drain ohmic layer 114, second gate structures 120, and passivation layer 122 of HEMT device layer 110, as shown in FIG. 9, according to some embodiments of the present disclosure.

In some embodiments of the present disclosure, ILD layer 124 can include silicon dioxide or a low-k dielectric material, such as a fluorosilicate glass, a carbon-doped silicon dioxide, a porous silicon dioxide, a porous carbon-doped silicon dioxide, a hydrogen silsesquioxane, a methylsilsesquioxane, a polyimide, a polynorbomene, a benzocyclobutene and a polytetrafluoroethylene. For forming ILD layer 124, a deposition process, such as chemical vapor deposition, plasma-enhanced chemical vapor deposition and spin coating, may be performed.

In some embodiments of the present disclosure, ILD layer 124 can be made of a flowable dielectric material, such as a flowable silicon oxide, a flowable silicon nitride, a flowable silicon oxynitride, a flowable silicon carbide, and a flowable silicon oxycarbide. ILD layer 124 can be deposited using a deposition method suitable for flowable dielectric materials, such as a flowable CVD (FCVD) process. Other materials and formation methods for ILD layer 124 are within the scope and spirit of this disclosure.

Referring to FIG. 2, in operation 222, contacts 126 can be formed to source/drain ohmic layer 114 and second gate structures 120, as shown in FIG. 9, according to some embodiments of the present disclosure. Contacts 126 can be formed by etching contact openings in ILD layer 124 that are aligned with source/drain ohmic layer 114 and second gate structures 120 using, for example, a fluorine-based plasma etching process. The contact openings can then be filled with metal using either a metal deposition process or a metal plating process such as electroplating or electro-less plating.

According to embodiments of the present disclosure, the design criteria for a GaN HEMT device can include reducing on-resistance R_{ds}-on without affecting the threshold voltage Vₜₕ. It is desirable for the threshold voltage Vₜₕ of a GaN HEMT device to be high enough to withstand a voltage spike and to prevent the voltage spike from inadvertently turning on the device. Meanwhile, it is desirable for the on-resistance R_{ds}-on to be as small as possible to reduce power dissipation. By inserting a second AlGaN layer, having a different composition, over the AlGaN—GaN heterojunction, it is possible to de-couple on-resistance R_{ds}-on from the threshold voltage Vₜₕ. The use of sidewall spacers and selective epitaxy can ensure that the second AlGaN layer is disposed adjacent to the gate, but not directly underneath the gate, so that the threshold voltage Vₜₕ is unaffected while on-resistance R_{ds}-on is reduced.

In some embodiments of the present disclosure, a device includes: a gallium nitride (GaN) layer on a substrate; first and second aluminum gallium nitride (AlGaN) layers on the GaN layer having different compositions from one another; a gate structure; and source and drain regions in contact with both the first and second AlGaN layers.

In some embodiments of the present disclosure, a device includes: forming a transition/buffer layer on a substrate; forming a channel layer on the transition/buffer layer; forming a first aluminum gallium nitride (AlGaN) layer above the channel layer; forming, above the first AlGaN layer, a gate structure having sidewall spacers; forming a second AlGaN layer adjacent to the gate structure; and forming source and drain ohmic contacts that includes the first and second AlGaN layers.

In some embodiments of the present disclosure, a structure includes: a channel layer including gallium nitride (GaN); first and second aluminum gallium nitride (AlGaN) layers on the channel layer; a first gate structure over the channel layer, the first gate structure including positively doped GaN (pGaN); a second gate structure over the first gate structure, the second gate structure including a metal; and source/drain regions in contact with both the first and second AlGaN layers.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a gallium nitride (GaN) layer on a substrate;
first and second aluminum gallium nitride (AlGaN) layers on the GaN layer having different compositions from one another;
a gate structure; and
source and drain regions in contact with both the first and second AlGaN layers.

2. The device of claim 1, wherein an aluminum concentration of the second AlGaN layer is greater than that of the first AlGaN layer.

3. The device of claim 2, wherein the aluminum concentration of the second AlGaN layer is in the range of about 40% to about 50%.

4. The device of claim 2, wherein the aluminum concentration of the first AlGaN layer is in the range of about 15% to about 20%.

5. The device of claim 1, further comprising sidewall spacers disposed on sides of the gate structure to block diffusion of aluminum between the second AlGaN layer and a region under the gate structure.

6. The device of claim 1, wherein the first AlGaN layer extends under the gate structure and the second AlGaN layer does not extend under the gate structure.

7. The device of claim 1, wherein the gate structure comprises a positively-doped GaN (pGaN) layer.

8. The device of claim 7, wherein the gate structure comprises a T-shaped metal gate on the pGaN layer.

9. The device of claim 7, wherein the pGaN layer is doped with magnesium.

10. The device of claim 1, wherein the second AlGaN layer is disposed over and in contact with the first AlGaN layer.

11. A method, comprising:
forming a transition/buffer layer on a substrate;
forming a channel layer on the transition/buffer layer;
forming a first aluminum gallium nitride (AlGaN) layer above the channel layer;
forming, above the first AlGaN layer, a gate structure having sidewall spacers;
forming a second AlGaN layer adjacent to the gate structure; and
forming source and drain ohmic contacts that comprise the first and second AlGaN layers.

12. The method of claim 11, wherein forming the second AlGaN layer comprises selectively epitaxially growing AlGaN having different concentrations of aluminum and gallium on exposed regions of the first AlGaN layer.

13. The method of claim 11, wherein forming the gate structure comprises forming a positively-doped gallium nitride (GaN) gate structure.

14. The method of claim 13, wherein forming the gate structure further comprises forming a metal gate on the positively-doped GaN gate structure.

15. The method of claim 11, wherein forming the gate structure comprises forming sidewall spacers that include one or more of an oxide, a nitride, and an oxynitride.

16. The method of claim 11, wherein the transition/buffer layer, the channel layer, and the first AlGaN layer are formed together as a superlattice, by epitaxial growth.

17. A structure, comprising:
a channel layer comprising gallium nitride (GaN);
first and second aluminum gallium nitride (AlGaN) layers on the channel layer;
a first gate structure over the channel layer, the first gate structure comprising positively doped GaN (pGaN);
a second gate structure over the first gate structure, the second gate structure comprising a metal; and
source/drain ohmic layers in contact with the first and second AlGaN layers.

18. The structure of claim 17, wherein the source/drain ohmic layers are metallic.

19. The structure of claim 17, wherein the first AlGaN layer has a thickness between about 150 Å and about 300 Å.

20. The structure of claim 17, wherein the structure is incorporated into one or more of a radio frequency (RF) power amplifier, an RF switch, an RF mobile communication network, a power converter, a dual voltage power supply, an AC-DC converter, and a satellite communication apparatus.
